(19) United States
(12) Patent Application Publication
(10) Pub. No.: US 2007/0264420 A1
(43) Pub. Date: Nov. 15, 2007

(54) Method of detecting the dryness of a water based composition used in an automated process

(76) Inventors: Ronald R. Davies, Eagan, MN (US); Merilee M. Reski, Woodbury, MN (US); Claudia Mosanu, Blaine, MN (US); Lee Z. Polance, White Bear Lake, MN (US); Joseph S. Hetzer, White Bear Lake, MN (US)

Correspondence Address: H.B. FULLER COMPANY, 1200 WILLOW LAKE BLVD., P.O. BOX 64683, ST. PAUL, MN, 55164-0683, US

(21) Appl. No.: 11/799,803

(22) Filed: May 3, 2007

Related U.S. Application Data
(60) Provisional application No. 60/797,397, filed on May 3, 2006.

(51) Int. Cl. D06L 3/12; C23C 16/52; B05D 3/02; B05D 7/00; B05C 11/00; C08J 7/18; B05B 5/00

(52) U.S. Cl. 427/8; 427/553; 427/372.2; 427/157; 427/407.1; 118/642; 118/665

(57) ABSTRACT

A method of optimizing an automated water based composition application system is disclosed. The method includes utilizing a fluorescent indicator to monitor the drying of the water based composition. The fluorescent indicator imparts to the composition a fluorescence change as the composition progresses from a wet condition to a dry condition. The invention also relates to an improved automated book binding method in which a fluorescent indicator is used to monitor the drying of a water based composition.

### CROSS-REFERENCE TO RELATED APPLICATIONS

This Application claims the benefit of priority to U.S. Provisional Application Ser. No. 60/797,397 filed May 3, 2006.

### FIELD OF THE INVENTION

The invention relates to a method of optimizing an automated water based composition application system. The invention also relates to an improved automated book binding method in which a fluorescent indicator is used to monitor the drying of a water based composition.

### BACKGROUND OF THE INVENTION

The automation of book binding has allowed the manufacture of books to proceed as a substantially continuous high speed process, which includes, such as, the printing and compiling the pages, or signatures, into book blocks, gluing the spines of book blocks, applying a covering material, and trimming.

Book blocks are normally manufactured either with a one step (or one-shot) adhesive application process, or a two-step (or two shot) adhesive application process. In a one step process, an adhesive composition (i.e., a one-shot adhesive) is applied directly onto the spine area of a book block. In a two-step process, however, a primer composition is first applied onto the spine area of the book block as the “first shot”. Then, a second adhesive composition (i.e., a second-shot adhesive) is applied onto the top surface of the primer composition as the “second shot”. To date, many two-step processes of binding book blocks utilize water-based compositions as a first shot and hot melt adhesive compositions as a second shot.

Water based compositions are often used as the first shot primer because they exhibit better penetration into the signatures (folded paper groups) due to their longer open times and lower viscosities. They are also less susceptible to the fluctuations in the ambient temperatures once the book is constructed. Water based compositions, however, require more time to set because the water contained therein must be removed before a hot melt adhesive can be applied. If the coating of the water-based composition is not sufficiently dried, the water remaining in the coating will splatter and/or blister when the second-shot hot melt adhesive is applied at a relatively high application temperature (e.g., from about 100° C. to about 200° C.). The blistering layer of the water-based composition cannot be bonded well to the spine area of the book block, resulting in defective products as well as delays in the book binding process itself. Also, the unset water based composition coating tends to peel off the book block and contaminates the second application pot containing the hot melt adhesive. Consequently, the hot melt adhesive loses its integrity due to its mixing with the liquid water based composition contaminate. Hence, the maximum line speed of manufacturing book blocks, as well as assembling books thereafter, is limited by the time needed to dry the water-based composition. Air-drying at ambient conditions is not fast enough so dryers and heat are typically used to expedite the drying of the water based composition to maintain reasonable production rates.

Currently, a high speed automated book binding production line produces more than 50 books per minute. To monitor the dryness of the water-based primer composition in such a high speed automated process line has been problematic. For example, to control the drying of the water based composition through operation variables such as dryer output, (or line speed, or drying time), drying temperature, air flow, etc., one has to temporarily shut down the production line from time to time to manually inspect the dryness of the water based composition. Alternatively, one will visually check the second shot hot melt adhesive pot for any signs of the contamination by a water based composition such as foam or white residue in the hot melt adhesive pot, which indicates that the wet water based composition has been picked up by the applicator that is applying the second shot hot melt adhesive, thereby contaminating the hot melt adhesive pot. Or one has to wait until books have been processed through the entire line to conduct a quality check on the finished books to detect the bonding problem. The water based composition contaminate found in the hot melt adhesive pot and/or the poor quality in bonding the books indicate that the water based composition is not sufficiently dried prior to the application of the second shot hot melt adhesive. As one way to avoid having to completely shut down the production line to check the dryness of the water based composition some operators run the line conservatively slow, which is particularly costly due to the downtime on the high-speed automated book binding equipments, or on any automated system utilizing water based adhesives where monitoring drying time is critical to a subsequent action. Running the equipments at their maximum possible speed while maintaining the high quality of work is obviously desirable.

Therefore, there is a need for a mechanism of detecting the dryness of a water based composition quickly and accurately, particularly in the high speed automated applications without having to shut down the application system from time to time. Additionally, it would be beneficial to have a mechanism of immediate feedback to an operator so that the operator can adjust the variables of the system to the optimal settings at any given time.

### SUMMARY OF THE INVENTION

In one aspect, the invention features a method of manufacturing a book including a book block that has a spine. The method includes (a) applying to the spine of the book block a water based composition that includes a fluorescent indicator and that exhibits a fluorescence change as the composition progresses from a wet condition to a dry condition; (b) drying the water based composition; (c) monitoring the moisture level of the water based composition by detecting the fluorescence change; and (d) optionally optimizing the manufacturing variables to speed up or to slow down the drying of the water based composition.

In one embodiment, the method further includes a step of applying a hot melt adhesive onto the top surface of the water-based composition that is in a dry condition.

In one embodiment, the fluorescence change is detected by measuring the change in the fluorescence intensity of the water based composition with a fluorimeter as the composition progresses from a wet condition to a dry condition.

In one embodiment, the fluorescence intensity change is reflected by a percentage change (% change). The water based composition exhibits a percentage change (% change) of at least 25%, or at least 40%, or at least 50% when the composition is sufficiently dried for the application of the subsequent adhesive such as a second shot adhesive, or a substrate.

In another embodiment, the fluorescence change is detected by visually inspecting the change in the fluorescent color of the water-based composition under an ultra-violet (UV) light as the composition progresses from a wet condition to a dry condition.

In one embodiment, the manufacturing variables are optimized through adjusting the line speed to speed up or slow down the drying of the water-based composition. Adjusting the line speed includes increasing or decreasing the line speed.

In one embodiment, the manufacturing variables are optimized through adjust the coat weight of the water-based composition. Adjusting the coat weight includes increasing or decreasing the amount of the water based composition to be applied to the spine area of a book block, or a substrate.

In another embodiment, the manufacturing variables are optimized through adjust the drying parameters such as the drying temperature, or the air flow rate, or the heat intensity.

In another aspect, the invention features a method of optimizing an automated water-based composition application system. The method includes (a) applying to a substrate a water based composition including a fluorescent indicator and exhibiting a fluorescence change as the composition progresses from a wet condition to a dry condition; (b) drying the water based composition; (c) monitoring the dryness of the water based composition by detecting the fluorescence change; and (d) optionally optimizing the manufacturing variables to speed up or slow down the drying of the water based composition.

In yet another aspect, the invention features a method of detecting the dryness of a water based composition used in an automated process. The method includes (a) applying to a substrate the water based composition including a fluorescent indicator and exhibiting a fluorescence change as the composition progresses from a wet condition to a dry condition; (b) drying the water based composition; and (c) detecting the dryness of the water based composition by monitoring the fluorescence change.

In yet another aspect, the invention features an optimized automated water based composition application system. The water-based composition includes a fluorescent indicator and exhibits a fluorescence change as the composition progresses from a wet condition to a dry condition. The application system includes (a) a means for applying the water based composition to a substrate; (b) a means for drying the water based composition; (c) a means for detecting the fluorescence change; and (d) optionally a means for optimizing the manufacturing variables to speed up or slow down the drying of the water based composition.

In yet another aspect, the invention features a book including a book block. The book block has a spine and a water based composition deposited on the spine. The water-based composition includes a fluorescent indicator and exhibits a fluorescence change as the composition progresses from a wet condition to a dry condition.

In yet another aspect, the invention features a water based composition including water, a water dispersible polymer, and a fluorescent indicator. The composition exhibits a fluorescence change as it progresses from a wet condition to a dry condition.

In one embodiment, the water based composition exhibits at least 25%, or at least 40%, or at least 50% change in fluorescence intensity using a fluorimeter as the composition progresses from a wet condition to a dry condition.

In yet another aspect, the invention features a method of using a fluorescent indicator in a water-based composition to monitor the dryness of the water based composition.

The improved methods of the present invention involve utilizing the water based composition of the present invention to determine the proper dryness of the composition without having to wait to see a problem. For example, the improved methods allow an operator to optimize the drying of the water based composition without sacrificing the quality of the end product or without having to stop the production line. The improved methods are suitable for the same or similar book binding systems as discussed above, or any existing automated systems utilizing water based compositions followed by the application of a subsequent adhesive, or a substrate. Such systems are improved by using a water based composition of the invention and by detecting the fluorescence change in fluorescent color on the water based composition-coated substrate with the assistance of an appropriately placed UV lamp or the like for the dryness of the composition. Alternatively, the dryness can be detected by measuring the fluorescence change in fluorescence intensity with the assistance of a fluorimeter. With the above detecting assistance, the operator can adjust the drying of the water based composition by increasing or decreasing the line speed, or changing other operation variables such as dryer output, drying time, drying temperature, air flow rate, heat intensity, etc. In doing so, the operator can optimize the systems to maximize quality outputs and energy efficiency.

Other features and advantages will be apparent from the following description of the preferred embodiments and from the claims.

### DETAILED DESCRIPTION OF THE INVENTION

The following terms are used throughout the specification.

“Indicator” refers to a fluorescent indicator.

“Fluorescent indicator” refers to a fluorescent dye that imparts a first (or initial) fluorescent color to a water based composition under a wet condition and a second (or final) fluorescent color under a dry condition. The first fluorescent color and the second fluorescent color are different such that a change in fluorescent color can be determined by a visual inspection under a UV light.

“Fluorescent indicator” also refers to a fluorescent dye that imparts a first (or initial) fluorescence intensity to a water based composition under a wet condition and a second(or final) fluorescence intensity under a dry condition. The first and the second fluorescence intensities are different such that a change in the fluorescence intensity can be determined by measuring the first and the second fluorescence intensities using a fluorimeter. Therefore, the water based composition including a fluorescent indicator in the invention exhibits a change either in fluorescent color or in fluorescence intensity as the water based composition progresses from a wet condition to a dry condition.

“Fluorescence change” refers to the above stated change either in fluorescent color or in fluorescence intensity from a wet condition to a dry condition.

“Fluorescence intensity change” or “a change in fluorescence intensity” refers to an absolute difference between the first fluorescence intensity value of a wet (or non-dried) water based composition including an indicator and the second fluorescence intensity value of the composition that is sufficiently dried.

“Visual color” refers to a color observable to a naked eye under visible (or white) light.

“Visual colorless” refers to lack of a color observable to a naked eye under visible (or white) light.

“Fluorescent color” refers to a color observable to a naked eye under a UV light.

“Fluorescent colorless” refers to lack of a color observable to a naked eye under a UV light.

“Change in fluorescent color” or “fluorescent color change” refers to a fluorescent color difference between the first fluorescent color of a wet (or non-dried) water based composition including an indicator and the second fluorescent color of the composition that is sufficiently dried. The difference in fluorescent color is visible to a naked eye under a UV light.

“First (or initial) fluorescent color” refers to the fluorescent color detected under a UV light when a water based composition of the invention containing an indicator is in a wet condition.

“Second (or final) fluorescent color” refers to the fluorescent color, or the fluorescent colorless detected under a UV light when the water based composition of the invention containing the indicator is in a dry condition.

“First (or initial) fluorescence intensity” refers to the fluorescence intensity detected by a fluorimeter when a water based composition of the invention containing an indicator is in a wet condition.

“Second (or final) fluorescence intensity” refers to the fluorescence intensity detected by the fluorimeter when the water based composition of the invention containing the indicator is in a dry condition.

“Moisture level” refers to the amount of water remaining in the water based composition of the invention. The moisutre level ranges from a wet condition to a dry condition.

“A wet condition” means the water based composition of the invention has not yet dried, and the composition exhibits either a first fluorescent color or a first fluorescence intensity.

“A dry condition” or “a dried water based composition”, or “sufficiently dry” or “sufficiently dried” means the water contained in the water based composition has evaporated, and the composition including the indicator exhibits either a second fluorescent color or a second fluorescence intensity. Under the dry condition, the water based composition including the indicator exhibits a percentage change (% change) in fluorescence intensity of at least about 25%, or at least about 40%, or at least about 50%, which indicates that the composition has dried to at least the point where the subsequent application of a subsequent composition, e.g., a hot melt adhesive, or a substrate, results in the desired bond (i.e., no blistering or charring, and the bond strength is not weakened due to the lack of contact caused by entraped water vapor). It is understood that a dried water based composition may contain some residual water content.

The improved book binding method of the invention includes applying to the spine area of a book block a water based composition that includes a fluorescent indicator and exhibits a fluorescence change as the composition progresses from a wet condition to a dry condition, drying the water based composition, detecting the fluorescence change to monitor the dryness of the water based composition, optionally optimizing manufacturing variables to speed up or slow down the drying of the water based composition, and optionally applying a hot melt adhesive onto the surface of the water based composition that is sufficiently dry.

The water based composition of the present invention refers to a water based primer composition, a water based adhesive composition, or a water based coating composition. The composition includes water based solutions, dispersions, emulsions, or suspensions.

The water based composition includes water, a water disperisble polymer, and a fluorescent indicator.

Useful water dispersible polymers include such as film forming adhesive latexes. Suitable water-dispersible film forming polymers include polyurethane dispersions, polychloroprene, styrene-butadiene dispersions, vinyl-vinylidene chloride, vinyl acetate homopolymers ethylene-vinyl chloride copolymers, ethylene-vinyl acetate copolymers, vinyl acetate-acrylic acid copolymers, vinyl acetate acrylates, acrylonitrite-butadiene copolymers, or other natural or synthetic water dispersible polymers e.g., polyvinyl alcohol, starch-based polymers, or protein-based polymers.

Examples of commercially available water dispersible polymer latexes include ethylene-vinyl acetate copolymer emulsions such as Airflex® 300, Airflex® 320, Airflex®.400, Airflex® 410, Airflex® 440H, Airflex® 465, Airflex® 7200 from Air Products & Chemicals Corp. (Allentown, Pa.), and Elvace®40705-00, Elvace®40706 from Forbo Adhesive, LLC (Research Triangle Park, N.C.); vinyl acrylic copolymer emulsion HBF PD2121 from HB Fuller Company (St. Paul, Minn.).

The fluorescent indicator is present in the water based composition in an amount of at least about 0.001%, or about 0.01% , or about 0.1%, or no greater than about 5% by weight, based on the total weight of the composition.

Useful fluorescent indicators can be in solid form or in liquid form, and include those such as xanthene based fluorescent dyes, pyranines, anthraquinones, benzopyrans, thioxanthenes, perylene imides or styrylbenzenes. Examples of the xanthene based fluorescent dyes include fluoresceins, rhodamines, cosines, phloxines, uranines, succineins, sacchareins, rosamines, or rhodols. Examples of commercially available fluorescent indicators include such as FD & C Green 8, and Intracid fluorescein, available from Sensient (St. Louis, Mo.); and Ultraphor® SFN and Ultraphor® SFG, available from BASF Corporation (Charlotte, N.C.).

It is known that a fluorescent indicator imparts to a water based composition a particular fluorescent color derived from the chromophore of that indicator. Therefore, the intensity of the color emitted by the chromophore of one indicator may vary from one indicator to another. It has been discovered that the efficiency of the methods of the invention depends on the selection of the indicators. Only those indicators that impart to the water based composition a significant change in fluorescence intensity as the composition progresses from a wet condition to a dry condition are suitable for the fluorimeter detection. In some embodiments, the water based compostion including a suitable indicator exhibits a percentage chang (% change) of at least about 25%, or at least about 40%, or at least about 50%. Examples of useful commerically available fluorescent indicators for a fluorimeter detection include such as Ultraphor® SFN and Ultraphor® SFG.

While some indicators are suitable for a fluorimeter detection, other indicators are suitable for the visual determination under a UV light. Examples of commercially available fluorescent indicators for the visual determination include such as FD & C Green 8 and Intracid fluorescein.

In one embodiment, the fluorescent indicators are those that impart to a water based composition a fluorescence change in fluoroscent color or in fluorescence intensity as the composition progresses from a wet condition to a dry condition. However, they do not impart to the composition a visual color under visible light when the composition is in a dry condition.

The water-based composition may optionally include other ingredients or additives such as starch, tackifying resin dispersions, plasticizers, rheology modifiers, defoamers/antifoaming agents, surfactants, stabilizers, preservatives/biocides, pigments, crosslinking agents, curing agents, fillers, adhesion promoters, and mixtures thereof.

The water based composition can be prepared by various processes including, for example, dispersing any optional ingredients in a polymer latex component in any convenient manner. The fluorescent indicator, either in solid form or liquid form, can be mixed into the composition at any point during the preparation. After screening the mixture to remove any agglomerated material, the composition is ready for use.

Other information regarding the water based composition, dispersible polymers, optional ingredients, etc. can be found in U.S. Pat. No. 4,702,496, U.S. Pat. No. 5,443,674 and U.S. Pat. No. 6,548,579, which are incorporated herein by reference.

Hot-melt adhesives employed in the two shot book binding method of the invention include any suitable hot melt adhesives in the book binding application. Examples of commercially available useful hot-melt adhesives include such as HM-0948M, HL-3142, HL-3282, HL-3316 and HL-3178X available from H.B. Fuller Company.

The water-based composition is particularly useful in the two shot automated book binding process. The composition is applied to the spine area of a book block to be bound. The composition thoroughly wets the spine area to form a primer layer for the application of a second shot adhesive upon drying. The primer also provides structural benefits to the bound book.

In one embodiment, the water based composition is applied by an application wheel onto a properly prepared book spine. The water based composition is applied generously with one wheel, pushed into the substrate by a second wheel, both running in the same direction, oftentimes clockwise. The excess composition is then removed by a third wheel running in the opposite direction, or counter-clockwise. In another embodiment, only two wheels are used, so the second wheel runs in the counter direction. Various scrapers and/or brushes can be added, in addition to the wheels, to remove excess water based composition.

The water based composition is then heated and dried by exposing to a thermal radiation provided by, for example, IR lamps, radiant heaters, gas flame burners, radio frequency dryers, or combinations thereof. The drying temperature and the total exposure time are selected to adequately dry and set the water based composition, while not damaging the primer coating, or the book pages, e.g., by yellowing, charring or burning. During the drying process, as its water content is reduced the water based composition coating decreases in thickness to yield a strong, flexible plastic film.

The dried water based composition layer is coated with a layer of a second shot adhesive, e.g., a hot melt adhesive. In one embodiment, in a continuous book binding operation, the hot-melt adhesive is applied to each individual book block by passing it over a heated reservoir of the adhesive that is fed onto a rotating wheel and doctored to the necessary thickness. Typically, the hot-melt adhesive is applied to the coating as a liquid melt heated to about 250° F. to about 400° F. (120° C. to 200° C.). A cover stock or paper is then applied to cover the individual page blocks and the books are trimmed.

In another aspect, the invention is related to a method of optimizing an automated water based composition application system. The method includes applying to a substrate a water based composition that includes a fluorescent indicator and exhibits a fluorescence change as the composition progresses from a wet condition to a dry condition; drying the water based composition; detecting the dryness of the water based composition by monitoring the fluorescence change; and optionally optimizing the manufacturing variables to speed up or slow down the drying of the water based composition.

In one embodiment, the fluorescence change is monitored via an automated analyzer unit.

In one embodiment, the method includes detecting the dryness of the water based composition by monitoring the fluorescence change and adjusting the drying of the composition via an automated computational means to determine the fluorescence change and to responsively optimize the manufacturing variables to speed up or slow down the drying of the composition.

In another aspect, the invention relates to an optimized automated water based composition application system. The application system includes a means for applying the water based composition to a substrate; a means for drying the water based composition; a means for detecting the fluorescence change; and optionally a means for optimizing the manufacturing variables to speed up or slow down the drying of the water based composition.

In one embodiment, a means for applying the water based composition to a substrate includes such as roll coater, wheel transfer roll, spray equipment, extruder, and the like.

In one embodiment, a means for drying the water based composition includes air forced oven, IR (infrared) light, air blower with or without heat, gas flames, radio frequency dryers, and the like.

In one embodiment, a means for detecting the fluorescence change includes UV light, fluorimeter.

In one embodiment, a means for monitoring the fluorescence change in the application system includes an automated analyzer unit arranged to monitor the fluorescent color change of the water based composition by visual determination under a UV light. In another embodiment, the automated analyzer unit monitors the fluorescence change of the water-based composition by measuring the fluorescence intensity change using a fluorimeter.

In one embodiment, the application system includes an automated computational means to responsively adjusting the drying of the water based composition by optimizing the manufacturing system variables, e.g., line speed, drying temperature, air flow rate, etc., depending on the fluorescence change detected. The computational means may include an automated analyzer unit arranged to monitor the fluorescent color or fluorescence intensity change of the water based composition, and an automated control unit constructed and arranged to compare results from the analyzer unit with the pre-programmed specifications and to responsively optimize the system variables to maximize the drying of the water based composition. For example, the computational means may optimize the drying parameters. Alternatively it may adjust the line speed of the application system.

In one embodiment, means for detecting the fluorescence change includes an automated analyzer unit, which monitors the fluorescence changes of the composition. In another embodiment, means for optimizing the manufacturing variables includes an automated control unit, which functions as the process controller. The automated control unit compares the results from the analyzer unit to programmed specifications and controls the variable of the manufacturing system. The controlled variables of the system include such as the line speed, the drying parameters, and the amount of the water based composition to be applied. The programmed specifications preferably include the fluorescent color or the fluorescence intensity of a water based composition that is sufficiently dry for the application of a hot melt adhesive, or other subsequent composition, or a substrate.

The invention is further illustrated by the following examples. All percentages used herein are by weight unless otherwise specified.

### EXAMPLES

### Test Procedures

Test procedures used in the examples include the following.

The fluorescent color of a water based composition including a fluorescent indicator is determined under an ultra-violet (UV) light (at 365 nm wavelength) by visual inspection.

The fluorescence intensity of a water-based composition including a fluorescent indicator is measured by a Leary Fluorimeter (at 365 nm wavelength).

### Examples 1 and 2

Water based compositions of Examples 1 and 2 are prepared according to Table I. The components are added into a container while stirring.

Each of the two samples is prepared as follows: A 10 mil layer of the water based composition is drawn down to a sheet of office paper with a bird bar applicator. Both wet samples exhibit white visual color under the visible (white) light. Each sample, while in a wet condition, is placed under a UV light. With visual observation, Example 1 exhibits a bright green fluorescent color, and Example 2 exhibits a yellowish green fluorescent color. The samples are then placed under IR light (4 bulbs at 50% intensity) to be completely dried*. The dried samples are then visually examined under the visible light and the UV light again. The results are shown in Table II.

TABLE I

| | | Ex. 1 | Ex. 2 |
|---|---|---|---|
| WB 1798 (%) | Water base primer | 99.98 | 99.98 |
| | composition available | | |
| | from H B Fuller Company | | |
| FD&C Green 8 (%) | Fluorescent Indicator | 0.02 | |
| Intracid Fluorescein (%) | Fluorescent Indicator | | 0.02 |

TABLE II

| | Ex. 1 | Ex. 2 |
|---|---|---|
| Visual color (in a wet condition) | White | White |
| Fluorescent Color (in a wet condition) | Bright | Yellowish |
| | green | green |
| Visual color (in a dry condition) | Clear | Clear |
| Fluorescent Color (in a dry condition) | Dull, | Colorless |
| | dark blue | |

* Samples are considered completely dried when the weight of the coated paper stops dropping. An analytical balance is used to monitor the weight loss due to the water evaporation during the drying.

### Examples 3 and 4

Water based compositions of Examples 3 and 4 are prepared according to Table III. The components are added into a container while stirring.

TABLE III

| | | Ex. 3 | Ex. 4 |
|---|---|---|---|
| WB 1798 (%) | Water base primer | 99.5 | 99.7 |
| | composition available | | |
| | from H B Fuller Company | | |
| FD&C Green 8 | Fluorescent Indicator | 0.5 | |
| (4% solution) (%) | | | |
| Ultraphor ® SFN | Fluorescent Indicator | | 0.3 |
| liquid (%) | | | |

Ten 3 mil and ten 5 mil films of each Example are drawn down on a sheet of office paper with a bird bar. The initial fluorescence intensity of each sample in wet condition is measured using a Leary Fluorimeter. The samples are then placed under IR light (4 bulbs at 50% intensity) to be completely dried. The final fluorescence intensity of each sample in dry condition is measured again using the same Leary Fluorimeter. The results are reported in Tables IV and V. The difference in fluorescence intensity and the percentage change (% change) are calculated and the values are also reported in Table IV and V. The percentage change (% change) is calculated according to the formula: (|F-I|/I)×100% (F: final intensity, I: initial intensity).

TABLE IV

| Ex. 3 (3 mils) | | | | Ex. 3 (5 mils) | | | |
|---|---|---|---|---|---|---|---|
| | | Difference | | | | Difference | |
| Initial | Final | in | % | Initial | Final | in | % |
| intensity | intensity | intensity | Change | intensity | intensity | intensity | Change |
| 70 | 42 | 27 | 38.57 | 97 | 66 | 31 | 31.96 |
| 79 | 53 | 26 | 32.91 | 98 | 64 | 34 | 34.69 |
| 77 | 52 | 25 | 32.47 | 95 | 62 | 33 | 34.74 |
| 63 | 46 | 17 | 26.98 | 98 | 69 | 29 | 29.59 |
| 83 | 48 | 35 | 42.17 | 94 | 57 | 37 | 39.36 |
| 72 | 44 | 28 | 38.89 | 97 | 62 | 35 | 36.08 |
| 72 | 51 | 21 | 29.17 | 95 | 61 | 34 | 35.79 |
| 72 | 45 | 27 | 37.50 | 92 | 60 | 32 | 34.78 |
| 80 | 51 | 29 | 36.25 | 97 | 61 | 36 | 37.11 |
| 75 | 50 | 25 | 33.33 | 93 | 62 | 31 | 33.32 |
| AVG | | | 34.82 | AVG | | | 34.74 |
| STDV | | | 4.7 | STDV | | | 2.71 |

TABLE V

| Ex. 4 (3 mils) | | | | Ex. 4 (5 mils) | | | |
|---|---|---|---|---|---|---|---|
| | | Difference | | | | Difference | |
| Initial | Final | in | % | Initial | Final | in | % |
| intensity | intensity | intensity | Change | intensity | intensity | intensity | Change |
| 41 | 81 | 40 | 49.38 | 43 | 98 | 55 | 56.12 |
| 42 | 88 | 46 | 52.27 | 42 | 99 | 57 | 57.58 |
| 43 | 84 | 41 | 48.81 | 41 | 97 | 56 | 57.73 |
| 42 | 91 | 49 | 53.85 | 40 | 99 | 59 | 59.60 |
| 39 | 95 | 56 | 58.95 | 36 | 95 | 59 | 62.11 |
| 41 | 86 | 45 | 52.33 | 33 | 92 | 59 | 64.13 |
| 40 | 93 | 53 | 56.99 | 35 | 93 | 58 | 62.37 |
| 40 | 99 | 59 | 59.60 | 37 | 95 | 58 | 61.05 |
| 35 | 68 | 33 | 48.53 | 40 | 94 | 54 | 57.45 |
| 42 | 80 | 38 | 47.50 | 39 | 90 | 51 | 56.67 |
| AVG | | | 52.82 | AVG | | | 59.48 |
| STDV | | | 4.44 | STDV | | | 2.78 |

### Example 5 and 6

Water based compositions of Examples 5 and 6 are prepared according to Table VI. The components are added into a container while stirring.

TABLE VI

| | | Ex. 5 | Ex. 6 |
|---|---|---|---|
| PD 0330 (%) | Polyvinyl acetate (PVAc) | 99.98 | 99.98 |
| | polymer emulsion Available | | |
| | from H. B. Fuller Company | | |
| FD&C Green 8 (%) | Fluorescent Indicator | 0.02 | |
| Intracid Fluorescein (%) | Fluorescent Indicator | | 0.02 |

Each of the two samples is prepared as follows: A 10 mil layer of the water based composition is drawn down to a sheet of office paper with a bird bar applicator. Both wet samples exhibit white visual color under the visible (white) light. Each sample, while in a wet condition, is placed under a UV light. With visual observation, the sample of Example 5 exhibits a bright green fluorescent color, and the sample of Example 6 exhibits a yellowish green fluorescent color. The samples are then placed under IR light (4 bulbs at 50% intensity) to be completely dried. The dried samples are then visually examined under the visible light and the UV light again. The results are shown in Table VII.

TABLE VII

| | Ex. 5 | Ex. 6 |
|---|---|---|
| Visual color (in a wet condition) | White | White |
| Fluorescent Color (in a wet condition) | Bright green | Yellowish |
| | | green |
| Visual color (in a dry condition) | Clear | Clear |
| Fluorescent Color (in a dry condition) | Dull, dark blue | Colorless |

### Example 7 and 8

Water based compositions of Examples 7 and 8 are prepared according to Table VIII. The components are added into a container while stirring.

TABLE VIII

| | | Ex. 7 | Ex. 8 |
|---|---|---|---|
| PD 0330 (%) | PVAc polymer emulsion | 99.5 | 99.7 |
| FD&C Green 8 | Fluorescent Indicator | 0.5 | |
| (4% solution) (%) | | | |
| Ultraphor ® SFN | Fluorescent Indicator | | 0.3 |
| liquid (%) | | | |

Ten 3 mil and ten 5 mil films of each Example are drawn down on a sheet of office paper with a bird bar. The initial fluorescence intensity of each sample in wet condition is measured using a Leary Fluorimeter. The samples are then placed under IR light (4 bulbs at 50% intensity) to be completely dried. The final fluorescence intensity of each sample in dry condition is measured again using the same Leary Fluorimeter. The results are reported in Tables IX and X. The difference in fluorescence intensity and the percentage change (% change) are calculated and the values are also reported in Table IX and X. The percentage change (% change) is calculated according to the formula:
(|F-I|/I)×100% (F: final intensity, I: initial intensity).

TABLE IX

| Ex. 7 (3 mils) | | | | Ex. 7 (5 mils) | | | |
|---|---|---|---|---|---|---|---|
| | | Difference | | | | Difference | |
| Initial | Final | In | % | Initial | Final | in | % |
| intensity | intensity | intensity | Change | intensity | intensity | intensity | Change |
| 80 | 52 | 28 | 35.00 | 98 | 70 | 28 | 28.57 |
| 78 | 53 | 25 | 32.05 | 95 | 67 | 27 | 29.47 |
| 87 | 56 | 31 | 35.63 | 97 | 63 | 34 | 35.05 |
| 83 | 55 | 28 | 33.73 | 98 | 69 | 29 | 29.59 |
| 80 | 49 | 31 | 38.75 | 99 | 70 | 29 | 29.29 |
| 82 | 53 | 29 | 35.37 | 93 | 65 | 28 | 30.11 |
| 82 | 51 | 31 | 37.80 | 96 | 71 | 25 | 26.04 |
| 80 | 50 | 30 | 37.50 | 96 | 62 | 34 | 35.42 |
| 86 | 51 | 35 | 40.70 | 97 | 72 | 25 | 25.77 |
| 83 | 52 | 31 | 37.35 | 99 | 70 | 29 | 29.29 |
| AVG | | | 36.39 | AVG | | | 29.86 |
| STDV | | | 2.53 | STDV | | | 3.19 |

TABLE X

| Ex. 8 (3 mils) | | | | Ex. 8 (5 mils) | | | |
|---|---|---|---|---|---|---|---|
| | | Difference | | | | Difference | |
| Initial | Final | in | % | Initial | Final | in | % |
| intensity | intensity | intensity | Change | intensity | intensity | intensity | Change |
| 61 | 41 | 20 | 32.79 | 68 | 48 | 20 | 29.41 |
| 62 | 48 | 20 | 32.26 | 64 | 39 | 25 | 39.06 |
| 63 | 44 | 19 | 30.16 | 70 | 44 | 26 | 37.14 |
| 62 | 41 | 21 | 33.87 | 65 | 46 | 19 | 29.23 |
| 69 | 45 | 24 | 34.78 | 68 | 45 | 23 | 33.82 |
| 64 | 46 | 18 | 28.13 | 69 | 48 | 21 | 30.43 |
| 60 | 43 | 17 | 28.33 | 67 | 42 | 25 | 37.31 |
| 60 | 49 | 17 | 25.76 | 67 | 46 | 21 | 31.34 |
| 65 | 48 | 17 | 26.15 | 62 | 42 | 20 | 32.26 |
| 62 | 44 | 18 | 29.03 | 65 | 45 | 20 | 30.77 |
| AVG | | | 30.38 | AVG | | | 33.08 |
| STDV | | | 2.87 | STDV | | | 3.58 |

Although described primarily and illustratively hereafter with reference to the book binding manufacturing, the invention will be recognized as having a broad applicability to a wide variety of manufacturing operations where notification that the a water based composition is sufficiently dried is desirable. Thus, the invention may be employed in specific embodiments for monitoring and controlling water based composition application systems of all types.

While numerous embodiments and examples have been disclosed herein, it should be apparent that modifications could be made without departing from the spirit and scope of the invention. Therefore, the appended claims are intended to cover all such modifications that are within the scope of this invention.

What is claimed are:

1. A method of manufacturing a book, said book comprising a book block that has a spine, said method comprising:
a) applying a water based composition to said spine of said book block, said water based composition comprising a fluorescent indicator and exhibiting a fluorescence change as said composition progresses from a wet condition to a dry condition; and
b) drying said water based composition;
c) monitoring said water based composition's moisture level by detecting said fluorescence change;
d) optionally optimizing manufacturing variables to speed up or to slow down the drying of said water based composition.

2. The method of claim 1, further comprising a step of applying a hot melt adhesive on top of the water based composition in a dry condition.

3. The method of claim 1, wherein said fluorescence change is a change in fluorescence intensity, and wherein said step c) comprises measuring the change in the fluorescence intensity.

4. The method of claim 1, wherein said composition exhibits a percentage change in fluorescence intensity of at least about 25%.

5. The method of claim 1, wherein said fluorescence change is a change in fluorescent color, and wherein said step c) comprises visually inspecting the change in the fluorescent color under a ultra-violet (UV) light.

6. The method of claim 1, wherein said optimizing the manufacturing variables (d) comprises adjusting a manufacturing line speed, or a coat weight of said composition, or a drying parameter.

7. The method of claim 1, wherein said water based composition comprises a water dispersible polymer chosen from polyurethane dispersions, polychloroprene, styrene-butadiene dispersions, vinyl-vinylidene chloride, vinyl acetate homopolymers, ethylene-vinyl chloride copolymers, ethylene-vinyl acetate copolymers, vinyl acetate-acrylic acid copolymers, acrylonitrite-butadiene copolymers, acrylics, starch-based polymers, protein-based polymers, or other natural or synthetic water dispersible polymers.

8. The method of claim 1, wherein said water based composition comprises from about 0.001% to about 5% by weight of said fluorescent indicator, based on the total weight of said water based composition.

9. The method of claim 1, wherein said fluorescent indicator comprises xanthene based fluorescent dyes, pyranines, anthraquinones, benzopyrans, thioxanthenes, perylene imides, or styrylbenzene.

10. The method of claim 1, wherein said fluorescent indicator comprises xanthene based fluorescent dyes that comprises fluoresceins, rhodamines, cosines, phloxines, uranines, succineins, sacchareins, rosamines, or rhodols.

11. The method of claim 1, wherein said water based composition further comprising an additive chosen from tackifying resin dispersions, plasticizers, rheology modifiers, antifoam agents, surfactants, biocides, pigments, crosslinkers, curing agents, fillers, adhesion promoters, starch, preservatives, or mixtures thereof.

12. A method of detecting dryness of a water based composition used in an automated process, comprising
a) applying said water based composition to a substrate, said water based composition comprising a fluorescent indicator and exhibiting a fluorescence change as said composition progresses from a wet condition to a dry condition;
b) drying said water based composition;
c) detecting the dryness of said water based composition by monitoring said fluorescence change.

13. The method of claim 12, wherein said fluorescence change comprises a change in fluorescence intensity or a change in fluorescent color, and wherein said step c) comprises measuring the change in the fluorescence intensity, or visually inspecting the change in the fluorescent color under a ultra-violet (UV) light.

14. The method of claim 12, wherein said composition exhibits a percentage change in fluorescence intensity of at least about 25%.

15. The method of claim 12, further comprising a step of adjusting the drying of said water based composition, which comprises adjusting a manufacturing line speed, or a coat weight of said water based composition, or a drying parameter.

16. A method of optimizing an automated water based composition application system, said method comprising:
a) applying a water based composition to a substrate, said water based composition comprising a fluorescent indicator and exhibiting a fluorescence change as said composition progresses from a wet condition to a dry condition; and
b) drying said water based composition;
c) detecting the dryness of said water based composition by monitoring said fluorescence change; and
d) optionally optimizing manufacturing variables to speed up or to slow down the drying of said water based composition.

17. The method of claim 16, wherein said fluorescence change comprises a change in fluorescence intensity or a change in fluorescent color, and wherein said step c) comprises measuring the change in the fluorescence intensity, or visually inspecting the change in the fluorescent color under an ultra-violet (UV) light.

18. The method of claim 16, wherein said water based composition exhibits a percentage change in fluorescence intensity of at least about 25%.

19. An automated water based composition application system comprising:
a) a means for applying said water based composition to a substrate, said water based composition comprising a fluorescent indicator and exhibiting a fluorescence change as said composition progresses from a wet condition to a dry condition;
b) a means for drying said water based composition;
c) a means for detecting said fluorescence change;
d) optionally a means for optimizing manufacturing variables to speed up or slow down the drying of said water based composition.

20. A book comprising a book block that has a spine and a water based composition deposited on said spine, wherein said water based composition comprising a fluorescent indicator that imparts a fluorescence change as said composition progresses from a wet condition to a dry condition.
